(19) United States
(12) Patent Application Publication
(10) Pub. No.: US 2007/0026553 A1
(43) Pub. Date: Feb. 1, 2007

(54) Method of forming a semiconductor device

(75) Inventors: Alastair Robert Buckley, Sheffield (GB); Georg Karl Hermann Bodammer, Edinburgh (GB); Stephen Andrew Whitelegg, Stockport (GB)

Correspondence Address: HOWSON AND HOWSON, SUITE 210, 501 OFFICE CENTER DRIVE, FT WASHINGTON, PA, 19034, US

(73) Assignee: MicroEmissive Displays Limited, Edinburgh (GB)

(21) Appl. No.: 10/550,244

(22) PCT Filed: Mar. 23, 2004
(86) PCT No.: PCT/GB04/01270

§ 371 Date: Oct. 4, 2006

(30) Foreign Application Priority Data
Mar. 24, 2003 (GB) 0306721.2

(51) Int. Cl. H01L 21/00

(52) U.S. Cl. 438/28; 438/42; 257/E51.022

(57) ABSTRACT

A method of forming a semiconductor device from a semiconductor substrate (1) comprising circuitry (2) and terminal means (3) for establishing electrical connection to the circuitry; and a sheet (4) for forming a further layer of the device, the sheet comprising at least one groove (5). Adhesive is applied to at least one of the substrate (1) and the sheet (4); the substrate and the sheet are then aligned in a position such that the groove (5) faces the terminal means (3); and the substrate and the sheet are then attached together by means of the adhesive.

### BACKGROUND TO THE INVENTION

This invention relates to a method of forming a semiconductor device comprising assembling at least two layers.

The invention is particularly, but not exclusively, applicable to forming an optoelectronic device from a semiconducting substrate incorporating active circuitry (e.g. a CMOS—complementary metal oxide semiconductor—wafer) and monochrome OLED (organic light emitting diode pixels) and a further translucent layer, for example of glass, comprising color filters providing a color device. Such a device is described in US-A1-20010052752.

A plurality of OLED arrays is formed on a single substrate. The substrate comprises metal bond pads around the edges of each array for establishing electrical connections to the circuitry of the array. A convenient method of attaching the translucent filter layer to the substrate would be to use an adhesive such as an ultraviolet curable epoxy adhesive. After attaching the filter layer to the substrate, the resulting assembly is singulated by cutting to obtain individual OLED devices.

However, excess adhesive would remain on the bond pads and must be removed using chemical cleaning agents. The cleaning process would be difficult and the agents could damage the encapsulation of the device.

### SUMMARY OF THE INVENTION

With the aim of alleviating the above mentioned disadvantages, from a first aspect, the present invention provides a method of forming a semiconductor device comprising providing a semiconductor substrate comprising circuitry and terminal means for establishing electrical connection to the circuitry; providing a sheet for forming a further layer of the device, the sheet comprising at least one groove; applying adhesive to at least one of said substrate and said sheet; and aligning said substrate and said sheet in a position such that said at least one groove faces said terminal means and attaching said substrate and said sheet together by means of said adhesive in said position. The adhesive may be applied solely to said sheet.

The terminal means may comprise a plurality of bond pads. In a method of an OLED device according to the invention, the semiconductor substrate comprises at least one array of OLEDs. The further layer may comprise a translucent layer, e.g. of glass, bearing filters, such as color filters.

In a particular embodiment of the invention the circuitry comprises a plurality of discrete circuit means each having terminal means at at least one edge thereof, and after attachment of the substrate to the surface said substrate and sheet are singulated by severing said sheet at the at least one groove to form a plurality of devices each comprising one of said circuit means. There may, for example, be a plurality of parallel grooves in the sheet and there may also be a further set of parallel grooves intersecting said plurality of parallel grooves at right angles, devices being contained in rectangular portions of the substrate delimited by sections of four intersecting grooves when the sheet and the substrate are attached. In this embodiment of the invention each circuit means may have terminal means on all four edges of said rectangular portion. The adhesive may be applied to the entire surface of the sheet, which surface is to be attached to the substrate, for example by spraying.

In an alternative embodiment, each circuit means has terminal means on only one edge thereof. In this embodiment the sheet may be severed along lines offset from lines along which the substrate is severed, said lines in said substrate and said lines in said sheet being aligned with said grooves but spaced from each other across the width of said grooves. This avoids the need to remove sections of the sheet The adhesive may be applied to parts only of the sheet, for example in continuous lines or lines of dots parallel to the grooves.

From a second aspect, the present invention provides a semiconductor device assembly comprising a semiconductor substrate comprising circuitry and terminal means for establishing electrical connection to the circuitry; and a sheet attached to the substrate by means of adhesive and forming a further layer of the device, the sheet comprising at least one groove facing and aligned with said terminal means.

The terminal means may comprise a plurality of bond pads. In an OLED device assembly according to the invention, the semiconductor substrate comprises at least one array of OLEDs. The further layer may comprise a translucent layer, e.g. of glass, bearing filters, such as color filters.

In a particular embodiment of the invention the circuitry comprises a plurality of discrete circuit means each having terminal means at least one edge thereof. There may, for example, be a plurality of parallel grooves in the sheet and there may also be a further set of parallel grooves intersecting said plurality of parallel grooves at right angles, devices being contained in rectangular portions of the substrate delimited by sections of four intersecting grooves when the sheet and the substrate are attached. In this embodiment of the invention each circuit means may have terminal means on all four edges of said rectangular portion.

In an alternative embodiment, each circuit means has terminal means on only one edge thereof. In this embodiment the sheet may comprise sheet channels for severing the sheet, offset from substrate channels along which the substrate is to be severed, said channels in said substrate and said channels in said sheet being aligned with said grooves but spaced from each other across the width of said grooves.

From a third aspect, the invention provides an optoelectronic device made according to the alternative embodiment of the inventive method defined above and comprising a semiconductor substrate comprising circuitry, light emitting elements and terminal means for establishing electrical connection to the circuitry; and a sheet attached to the substrate by means of adhesive and forming a further layer of the device, the sheet having a portion extending beyond the substrate, said portion having been formed during the step of severing the sheet along lines offset from lines along which the substrate is severed.

The terminal means may comprise a plurality of bond pads. In an OLED device according to the invention, the semiconductor substrate comprises at least one array of OLEDs. The further layer may comprise a translucent layer, e.g. of glass, bearing filters, such as color filters.

### BRIEF DESCRIPTION OF THE DRAWINGS

Particular embodiments of the invention will now be described, by way of example only, with reference to the accompanying drawings, in which:

FIG. 1 is a schematic fragmentary view of a substrate for use in the invention;

FIG. 2 is a schematic fragmentary view of a sheet of glass for attaching to the substrate of FIG. 1;

FIG. 3 is a schematic transverse section through an assembly formed from the substrate of FIG. 1 and the sheet of FIG. 2;

FIG. 4 is a schematic transverse section through an alternative assembly; and

FIG. 5 shows the assembly of FIG. 4 after singulation.

### DETAILED DESCRIPTION OF PARTICULAR EMBODIMENTS

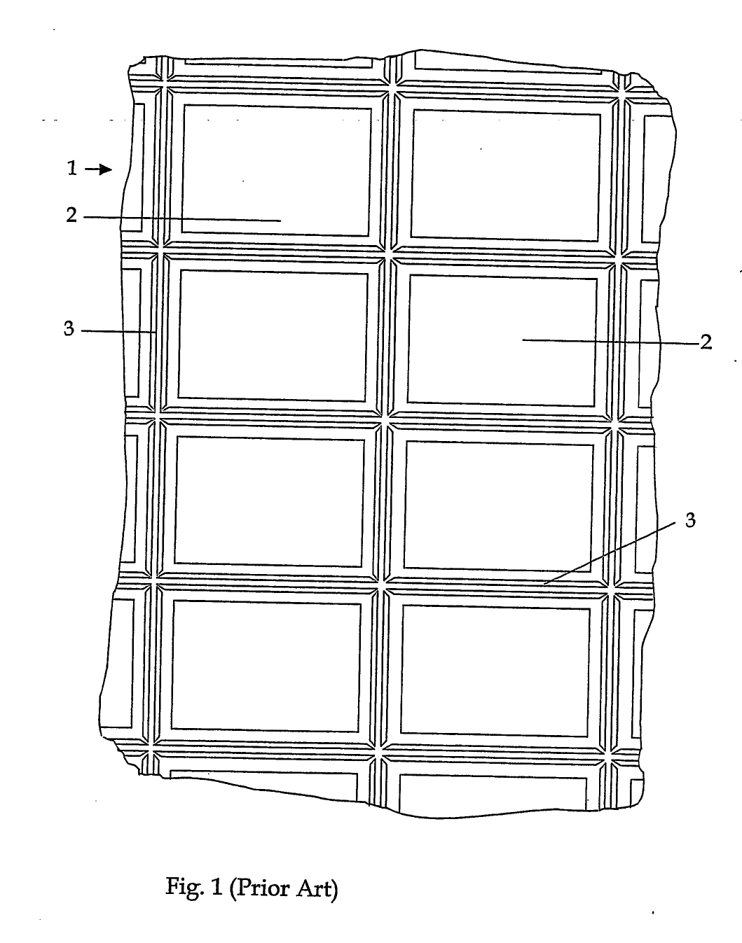

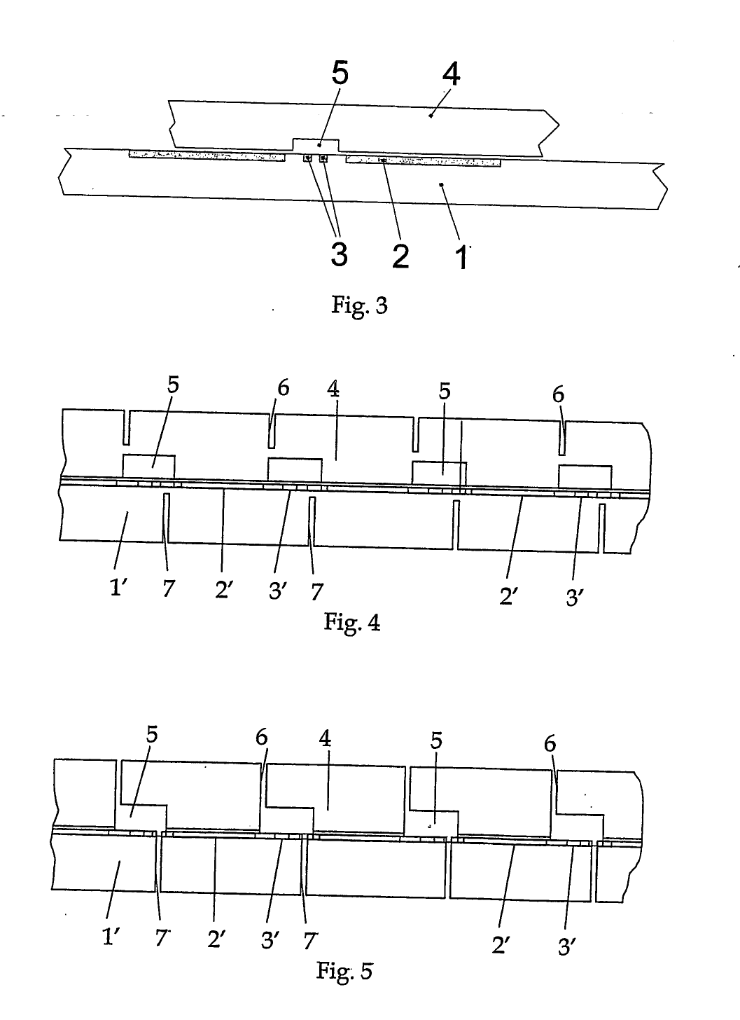

FIG. 1 shows part of a substrate 1 comprising a CMOS wafer bearing a number of monochrome OLED arrays 2 which have been fabricated on the active circuitry. Each array is rectangular and has bond pads 3 along all four sides. In FIG. 3 each trapezium denotes a line of bond pads, connections between the bond pads 3 and the OLED arrays 2 being omitted for clarity. In addition to the organic light emitting diodes, the substrate comprises further layers such as encapsulating and electrode layers.

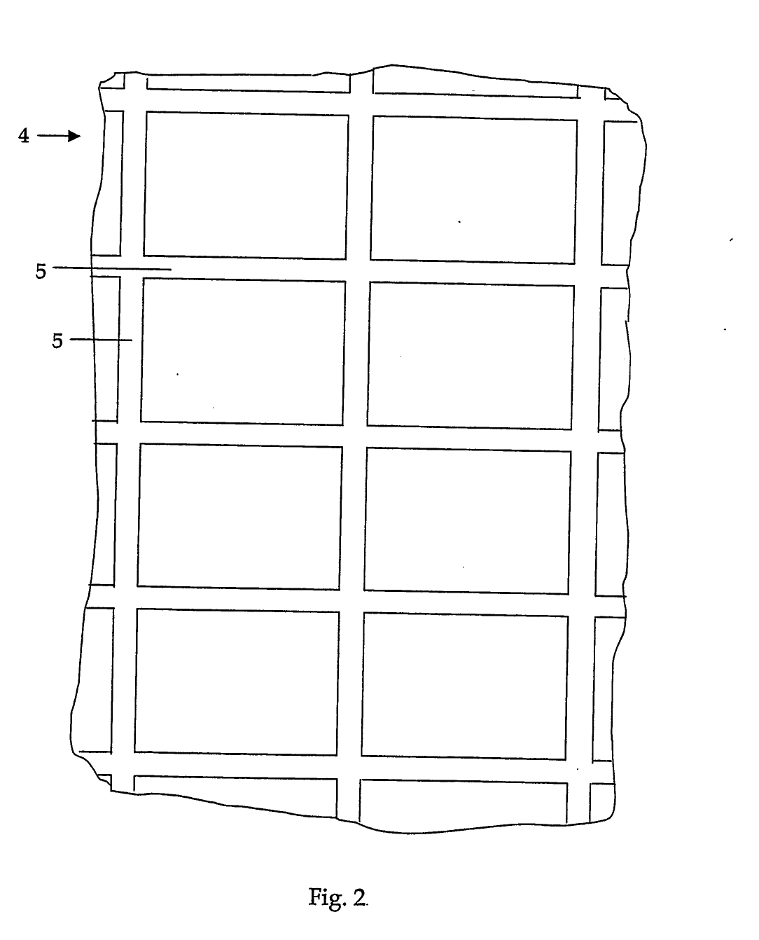

FIG. 2 shows part of a glass plate 4 for attaching to the substrate of FIG. 1. A crisscross network of grooves 5, having a depth of e.g. 0.2 mm and corresponding to the locations of the bond pads 3 of the substrate 1 has been etched in the plate 4. The plate bears color filters (not shown) for defining colored pixels of an optoelectronic device.

A transparent UV curable epoxy adhesive 6 is sprayed over the entire surface of the plate 4 including the grooves 5, in a layer of uniform thickness (e.g. 5 μm). The plate 4 and the substrate 1 are then assembled as shown in FIG. 3. Since the grooves 5 are aligned with the bond pads 3, no adhesive contacts the latter.

The assembly of FIG. 3 is singulated preferably by sawing through the substrate 1 at the location of the scribe channels between the bond pads 3 of adjacent devices, and by sawing through the plate 4 at both edges of each groove 5, removing the glass above the groove. To prevent damage the saw cuts may be terminated e.g. 50 μm from the interface between the substrate 1 and the plate 4, the assembly then being broken at the saw cuts.

FIG. 4 shows an alternative assembly in which OLED arrays 2′ of substrate 1′ have rows of bond pads 3′ along one side only.

Saw cuts 6 are made in glass plate 4 at only one edge of each of the grooves 5. These saw cuts are offset, e.g. by 1.4 mm, from cuts 7 in substrate 1′. The substrate 1′ and the plate 4 are broken at the saw cuts 7, 6 respectively to give the singulated devices shown in FIG. 5. In this embodiment it is not necessary to remove sections of glass from the plate.

As an alternative to spraying adhesive over the entire surface of the plate 4, adhesive could be applied to the plate in continuous lines or lines of dots, parallel to the grooves 5, for example using a robot. This is particularly appropriate in the embodiment shown in FIGS. 4 and 5. The adhesive spreads when the plate 4 is pressed against the substrate 1′, but flows along the inner surface of the grooves 5 rather than on to the bond pads 3′, due to the nature of the surface of the glass.

All forms of the verb “to comprise” used in this specification have the meaning “to consist of or include”.

1. A method of forming a semiconductor device comprising a semiconductor substrate comprising circuitry and terminal means for establishing electrical connection to the circuitry; providing a sheet for forming a further layer of the device, the sheet comprising at least one groove; applying adhesive to at least one of said substrate and said sheet; and aligning said substrate and said sheet in a position such that said at least one groove faces said terminal means and attaching said substrate and said sheet together by means of said adhesive in said position.

2. A method according to claim 1, wherein the adhesive is applied solely to said sheet.

3-15. (canceled)

16. A semiconductor device assembly comprising a semiconductor substrate comprising circuitry and terminal means for establishing electrical connection to the circuitry; and a sheet attached to the substrate by means of adhesive and forming a further layer of the device, the sheet comprising at least one groove facing and aligned with said terminal means.

17. A semiconductor device assembly according to claim 16, wherein the terminal means comprise a plurality of bond pads.

18-32. (canceled)

33. A method according to claim 1, wherein the terminal means comprises a plurality of bond pads.

34. A method according to claim 1, wherein the semiconductor substrate comprises at least one array of organic light emitting diodes.

35. A method according to claim 34, wherein the further layer comprises a translucent layer.

36. A method according to claim 35, wherein the translucent layer is glass.

37. A method according to claim 35, wherein the translucent layer bears color filters.

38. A method according to claim 1, wherein the circuitry comprises a plurality of discrete circuit means each having terminal means at at least one edge thereof, and after attachment of the substrate to the surface said substrate and sheet are singulated by severing said sheet at the at least one groove to form a plurality of devices each comprising one of said circuit means.

39. A method according to claim 38, wherein the sheet comprises a plurality of parallel grooves and a further set of parallel grooves intersecting said plurality of parallel grooves at right angles, devices being contained in rectangular portions of the substrate delimited by sections of four intersecting grooves when the sheet and the substrate are attached.

40. A method according to claim 39, wherein each circuit means has terminal means on all four edges of said rectangular portion.

41. A method according to claim 38, wherein each circuit means has terminal means on only one edge thereof.

42. A method according to claim 41, wherein the sheet is severed along lines offset from lines along which the substrate is severed, said lines in said substrate and said lines in said sheet being aligned with said grooves but spaced from each other across the width of said grooves.

43. A method according to claim 41, wherein the adhesive is applied to parts only of the sheet.

44. A method according to claim 43, wherein the adhesive is applied to the sheet in lines parallel to the grooves.

45. A method according to claim 1, wherein the adhesive is applied to the entire surface of the sheet, which surface is to be attached to the substrate.

46. A semiconductor device assembly according to claim 16, wherein the semiconductor substrate comprises at least one array of organic light emitting diodes.

47. A semiconductor device assembly according to claim 46, wherein the further layer comprises a translucent layer.

48. A semiconductor device assembly according to claim 47, wherein the translucent layer is of glass.

49. A semiconductor device assembly according to claim 47, wherein the translucent layer bears color filters.

50. A semiconductor device assembly according to claim 16, wherein the circuitry comprises a plurality of discrete circuit means each having terminal means on at least one edge thereof.

51. A semiconductor device assembly according to claim 50, wherein the sheet comprises a plurality of parallel grooves and a further set of parallel grooves intersecting said plurality of parallel grooves at right angles, devices being contained in rectangular portions of the substrate delimited by sections of four intersecting grooves when the sheet and the substrate are attached.

52. A semiconductor device assembly according to claim 51, wherein each circuit means has terminal means on all four edges of said rectangular portion.

53. A semiconductor device assembly according to claim 50, wherein each circuit means has terminal means on only one edge thereof.

54. A semiconductor device assembly according to claim 53, wherein the sheet comprises sheet channels for severing the sheet, offset from substrate channels along which the substrate is to be severed, said channels in said substrate and said channels in said sheet being aligned with said grooves but spaced from each other across the width of said grooves.

55. An optoelectronic device prepared by a process comprising the steps of:
providing a semiconductor substrate comprising circuitry, light emitting elements and terminal means for establishing electrical connection to the circuitry, the circuitry comprising a plurality of discrete circuit means each having terminal means on one edge thereof;
providing a sheet for forming a further layer of the device, the sheet comprising at least one groove;
applying adhesive to at least one of said substrate and said sheet;
aligning said substrate and said sheet in a position such that said at least one groove faces said terminal means; and
attaching said substrate and said sheet together by means of said adhesive in said position;
after attachment of the substrate to the surface, said substrate and sheet are singulated by severing said sheet at the at least one groove to form a plurality of devices each comprising one of said circuit means;
said sheet having a portion extending beyond the substrate, said portion having been formed during the step of severing the sheet along lines offset from lines along which the substrate is severed.

56. An optoelectronic device according to claim 55, wherein the terminal means comprise a plurality of bond pads.

57. An optoelectronic device according to claim 56, wherein the semiconductor substrate comprises at least one array of organic light emitting diodes.

58. An optoelectronic device according to claim 57, wherein the further layer comprises a translucent layer.

59. An optoelectronic device according to claim 58, wherein the translucent layer is of glass.

60. An optoelectronic device according to claim 58, wherein the translucent layer bears color filters.
